(19) United States
(12) Patent Application Publication
(10) Pub. No.: US 2024/0332035 A1
(43) Pub. Date: Oct. 3, 2024

(54) Semiconductor Device and Method of Forming Interconnect Structure with Graphene Core Shells for 3D Stacking Package

(71) Applicant: STATS ChipPAC Pte. Ltd., Singapore (SG)

(72) Inventors: YongMoo Shin, Incheon (KR); HeeSoo Lee, Incheon (KR); SuJeong Kwon, Incheon (KR)

(73) Assignee: STATS ChipPAC Pte. Ltd., Singapore (SG)

(21) Appl. No.: 18/193,942

(22) Filed: Mar. 31, 2023

(51) Int. Cl. H01L 21/56; H01L 23/29; H01L 23/31; H01L 23/538; H01L 25/065

(52) U.S. Cl. CPC H01L 21/565; H01L 21/563; H01L 23/295; H01L 23/3128; H01L 23/5389; H01L 25/0657; H01L 2225/06548

(57) ABSTRACT

A semiconductor device has a substrate and a first electrical component disposed over the substrate. A first encapsulant is deposited over the first electrical component and substrate. An interconnect structure including a graphene core shell is formed over or through the first encapsulant. The graphene core shell has a copper core or silver core. The interconnect structure has a plurality of cores covered by graphene and the graphene is interconnected within the interconnect structure to form an electrical path. The interconnect structure has thermoset material or polymer or composite epoxy type matrix and the graphene core shell is embedded within the thermoset material or polymer or composite epoxy type matrix. A second electrical component is disposed over the first encapsulant. A second encapsulant is deposited over the second electrical component. A shielding layer is formed over the second encapsulant. The shielding layer can have a graphene core shell.

### FIELD OF THE INVENTION

The present invention relates in general to semiconductor devices and, more particularly, to a semiconductor device and method of forming an interconnect structure with graphene core shells for a 3D stacking package.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into an Sip module for higher density in a small space and extended electrical functionality. Within the SIP module, semiconductor die and IPDs are disposed on a substrate for structural support and electrical connection through a vertical and horizontal interconnect structure. An encapsulant is deposited over the semiconductor die, IPDs, and substrate.

The interconnect structure can be made with copper (Cu) as a cost-effective material with reasonable electrical conductivity. The vertical interconnect structure is typically formed with a via on the order of 200-400 micrometers (μm). Unfortunately, Cu is subject to oxidation in the atmosphere. An interconnect structure robust to the environment with even better electrical conductivity is desired.

### BRIEF DESCRIPTION OF THE DRAWINGS

FIGS. 1a-1c illustrate a semiconductor wafer with a plurality of semiconductor die separated by a saw street;

FIGS. 2a-2l illustrate a process of forming an interconnect structure with graphene core shells for a 3D stacking package;

FIGS. 3a-3b illustrate further detail of the graphene core shell within the shielding layer;

FIGS. 4a-4c illustrate a process of forming a graphene core shell;

FIGS. 5a-5b illustrate using EHD jet printing to deposit the shielding material over the encapsulant;

FIG. 6 illustrates using aerosol jet printing to deposit the shielding material over the encapsulant; and

FIG. 7 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

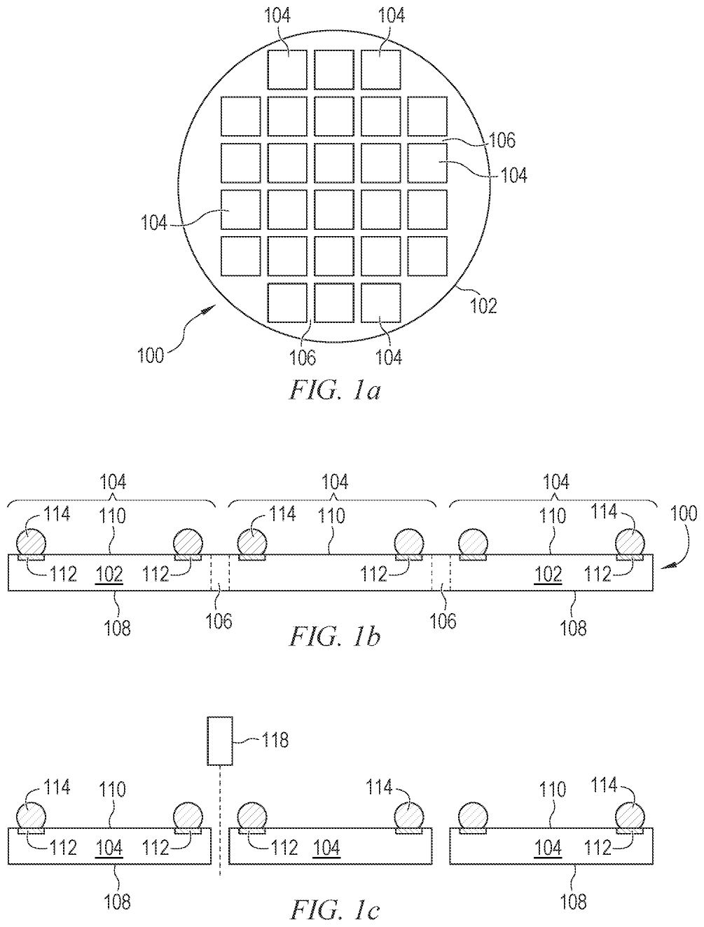

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm). Alternatively, wafer 100 can be a mold surface, organic or inorganic substrate, or target substrate suitable for graphene transfer.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), Cu, tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

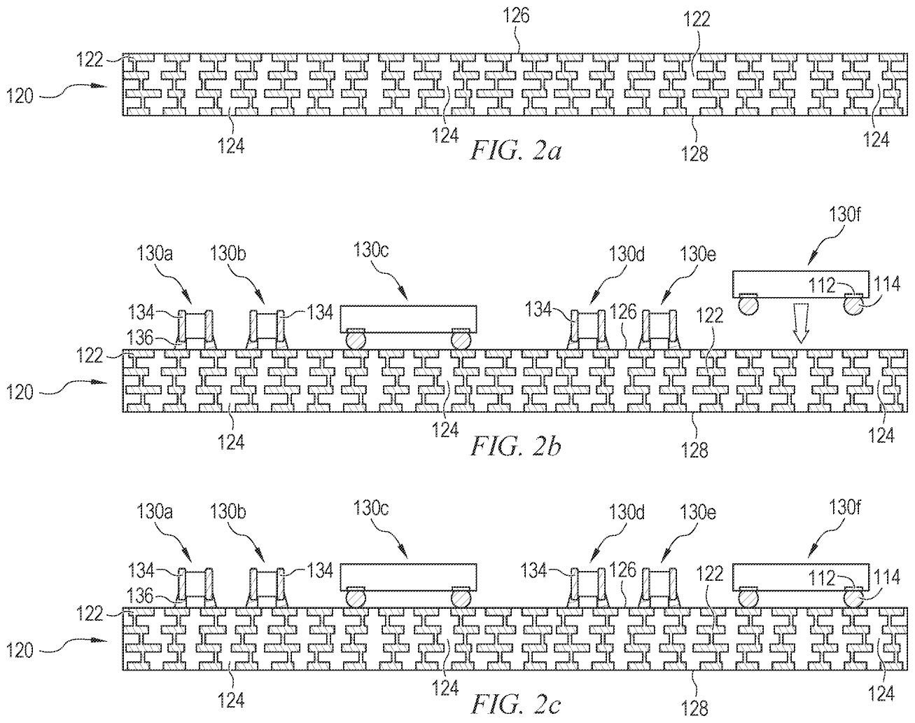

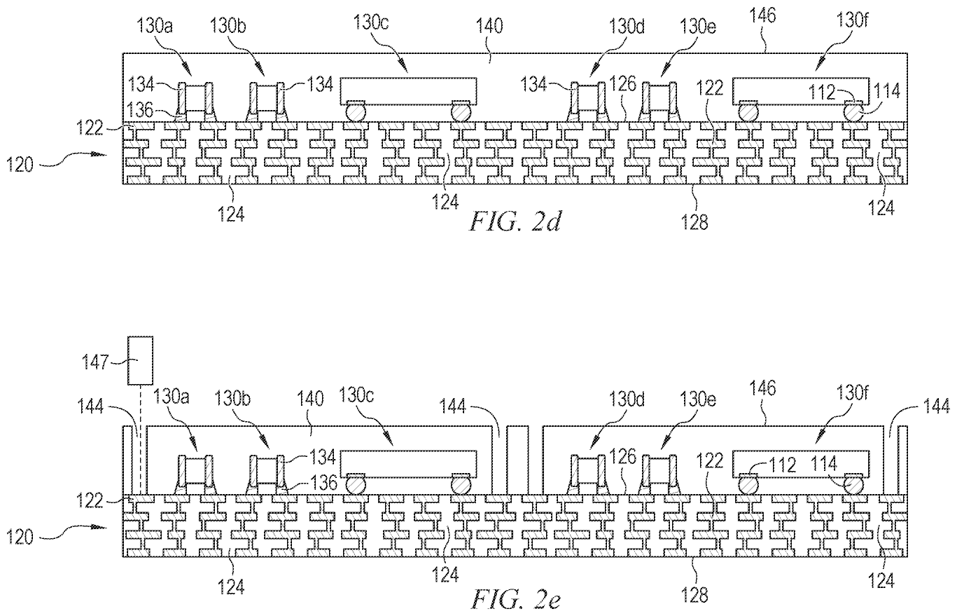

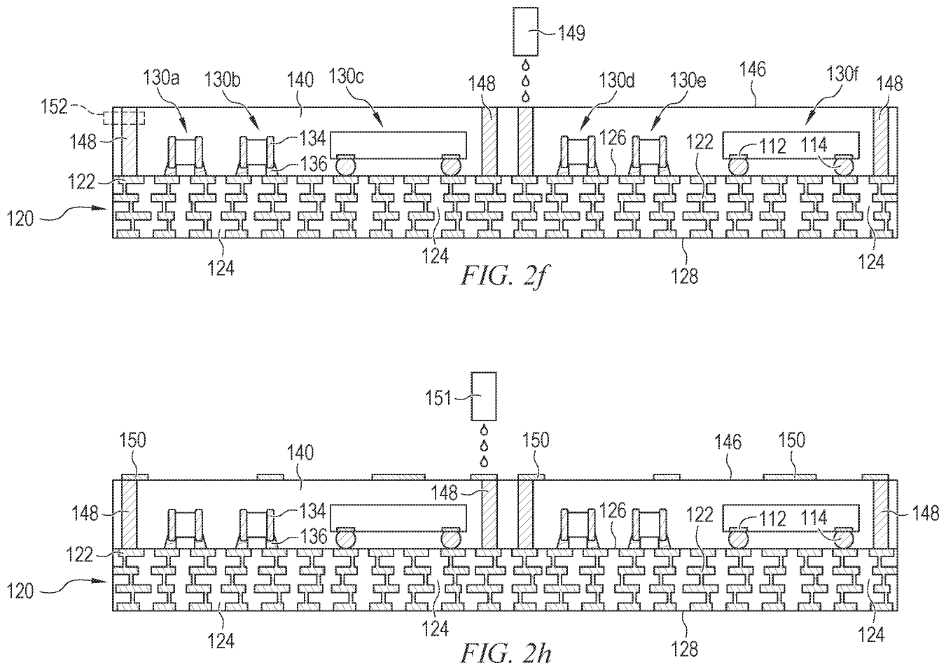

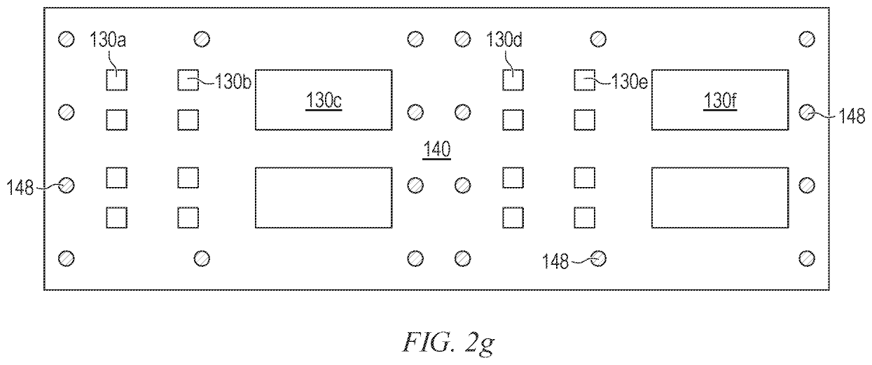

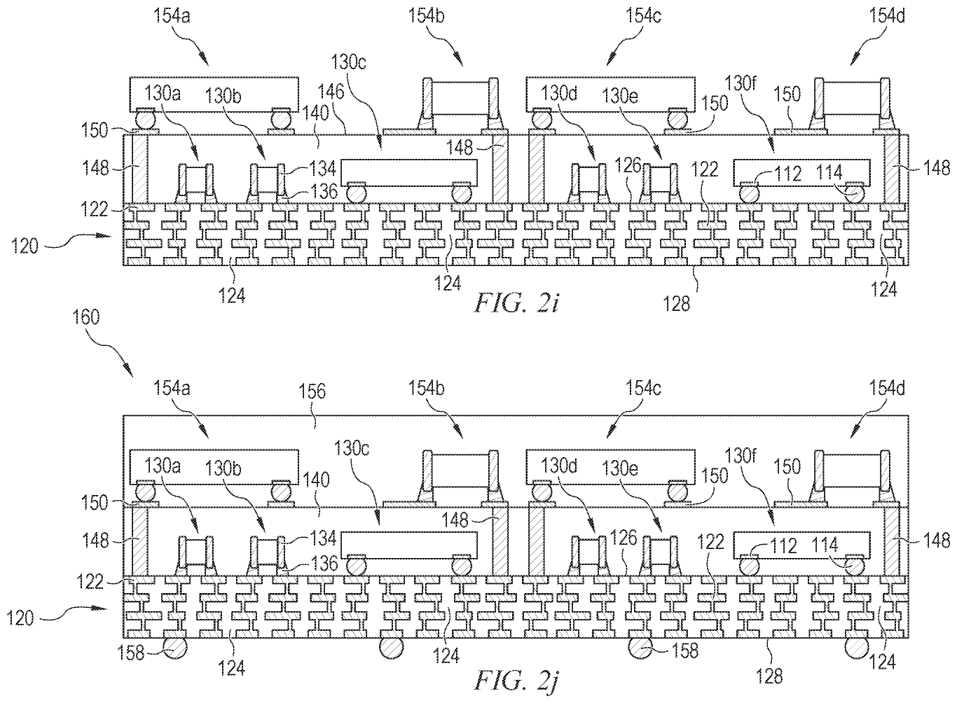

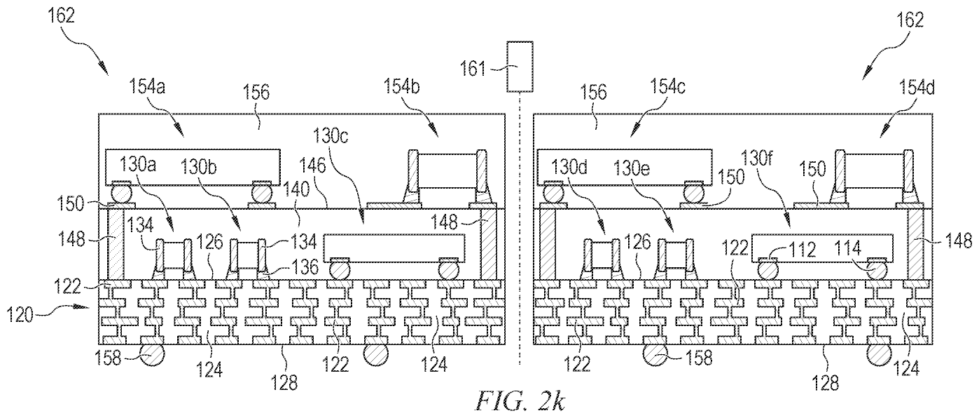

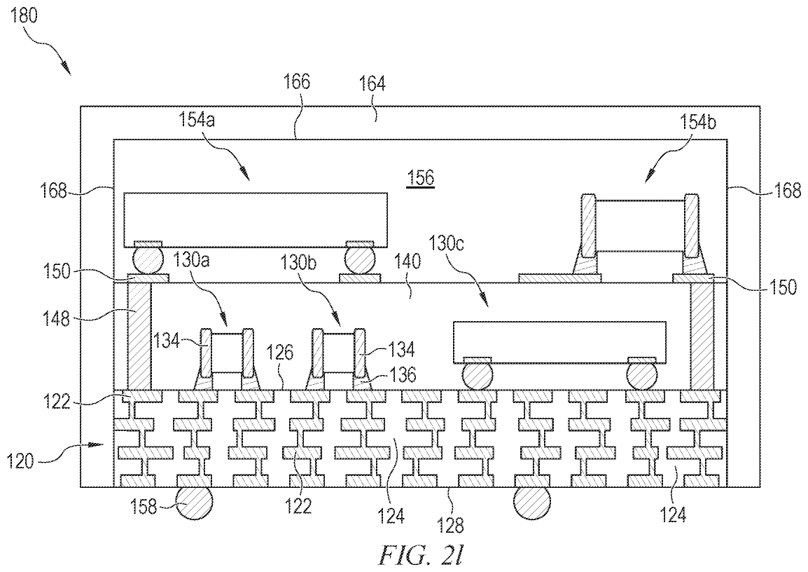

FIGS. 2a-2l illustrate a process of forming an interconnect structure with graphene core shells for a 3D stacking package. FIG. 2a shows a cross-sectional view of multi-layered interconnect substrate 120 including conductive layers 122 and insulating layer 124. Conductive layer 122 can be one or more layers of Al, Cu, Sn, Ni, Au, Ag, or other suitable electrically conductive material. Conductive layers can be formed using PVD, CVD, electrolytic plating, electroless plating process, or other suitable metal deposition process. Conductive layer 122 provides horizontal electrical interconnect across substrate 120 and vertical electrical interconnect between top surface 126 and bottom surface 128 of substrate 120. Portions of conductive layer 122 can be electrically common or electrically isolated depending on the design and function of semiconductor die 104 and other electrical components. Insulating layer 124 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers can be formed using PVD, CVD, printing, lamination, spin coating, spray coating, sintering or thermal oxidation. Insulating layer 124 provides isolation between conductive layers 122.

In FIG. 2b, electrical components 130a-130f are disposed on surface 126 of interconnect substrate 120 and electrically and mechanically connected to conductive layers 122. For example, electrical components 130a, 130b, 130d, and 130e can be discrete electrical devices, or IPDs, such as a diode, transistor, resistor, capacitor, and inductor. Electrical components 130 and 130f can be, or made similar to, semiconductor die 104 from FIG. 1c with bumps 114 oriented toward surface 126 of substrate 120. Alternatively, electrical components 130a-130f can include other semiconductor die, semiconductor packages, surface mount devices, RF components, discrete electrical devices, or integrated passive devices (IPD).

Electrical components 130a-130f are positioned over substrate 120 using a pick and place operation. Electrical components 130a-130f are brought into contact with conductive layer 122 on surface 126 of substrate 120. Terminals 134 of electrical components 130a, 130b, 130d, and 130e are electrically and mechanically connected to conductive layer 122 using solder or conductive paste 136. Electrical components 130a and 130f are electrically and mechanically connected to conductive layer 122 by reflowing bumps 114. FIG. 2c illustrates electrical components 130a-130f electrically and mechanically connected to conductive layers 122 of substrate 120.

In FIG. 2d, encapsulant or molding compound 140 is deposited over and around electrical components 130a-130f and substrate 120 using a paste printing, compressive molding, transfer molding, liquid encapsulant molding, vacuum lamination, spin coating, or other suitable applicator. Encapsulant 140 can be liquid or granular polymer composite material, such as epoxy resin with filler, epoxy acrylate with filler, or polymer with proper filler. Encapsulant 140 is non-conductive, provides structural support, and environmentally protects the semiconductor device from external elements and contaminants.

In FIG. 2e, a portion of encapsulant 140 is removed by etching or laser direct ablation (LDA) using laser 147 to form via or opening 144 and expose conductive layer 122. Vias 144 have a diameter or width of 50-70 μm and pitch of 100-140 μm.

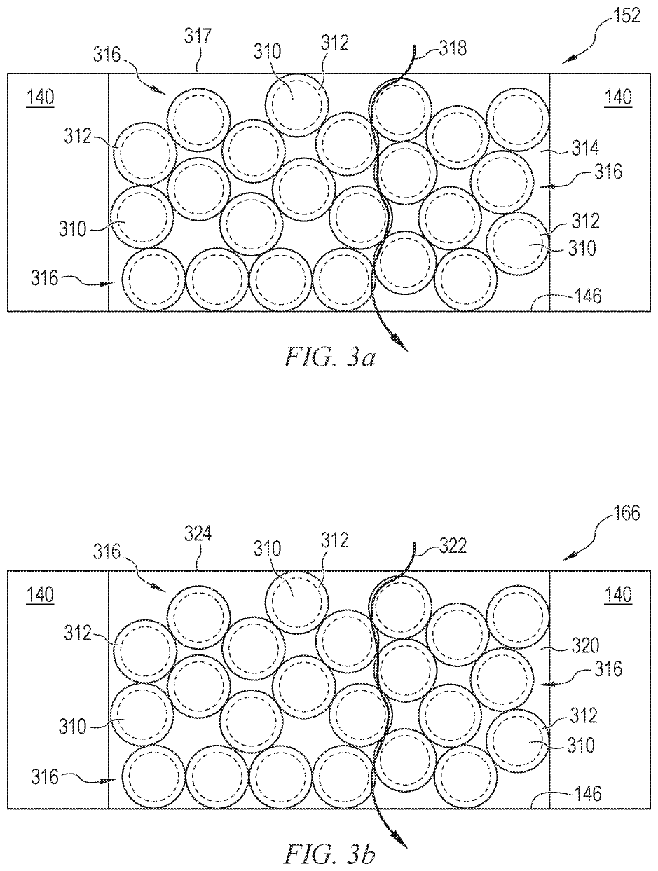

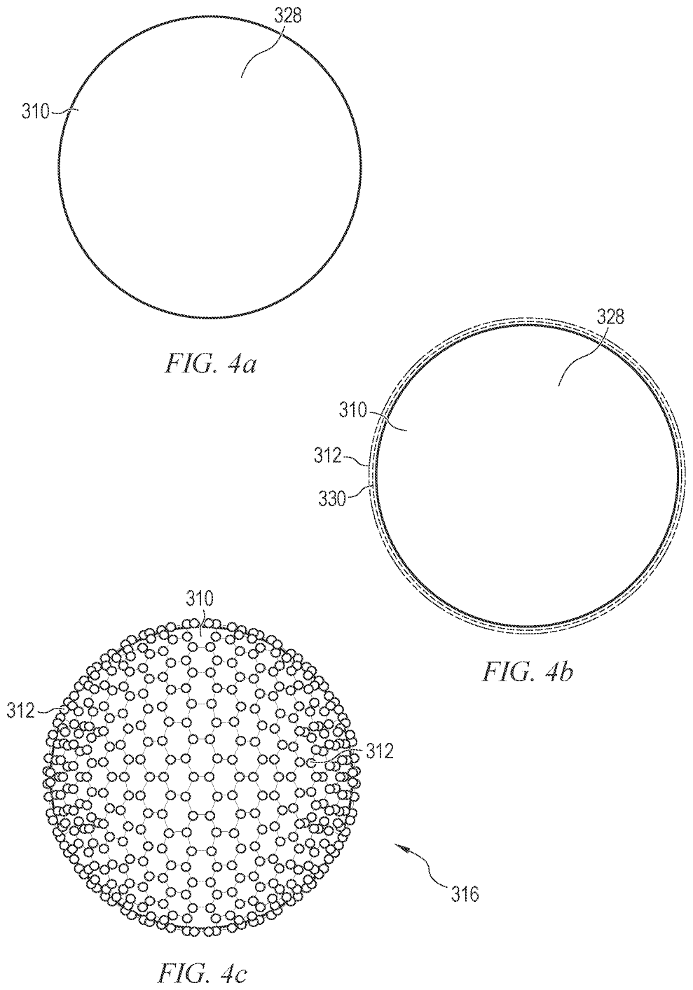

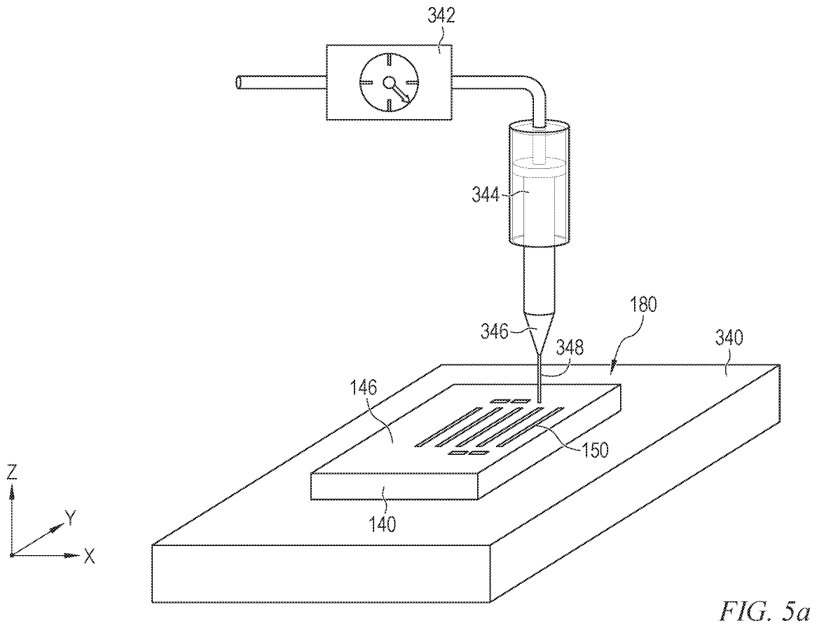

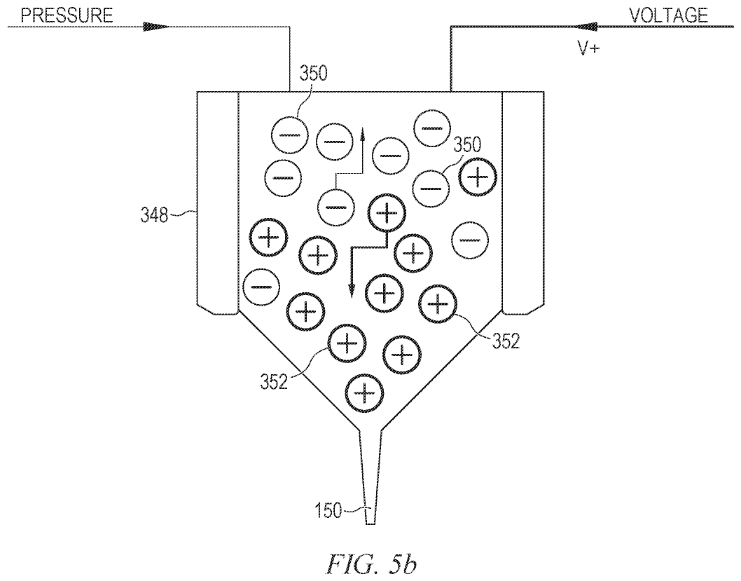

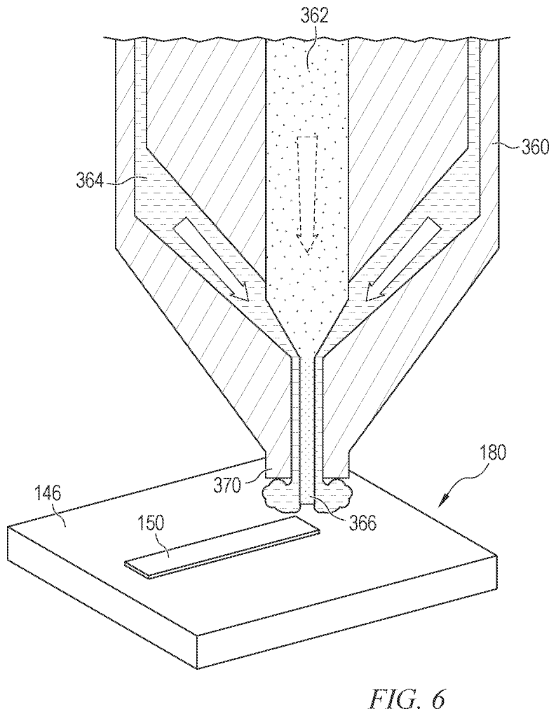

In FIG. 2f, electrically conductive material 148 is deposited, printed, or otherwise formed in vias 144 to provide a vertical electrical interconnect structure across, over, or through encapsulant 140. In one embodiment, conductive material 148 is printed or dispensed in vias 144 with printer or dispenser 149. Further detail of forming conductive material 148 is described in FIGS. 5a-5b and 6. Conductive material 148 can be one or more layers of a matrix, such as thermal set material or polymer, with graphene covered core shells embedded within the matrix, see further description in FIGS. 3a-3b and 4a-4c. Alternatively, electrically conductive material 148 is deposited in vias 144 using evaporation, electrolytic plating, electroless plating, ball drop, screen printing process, injector, or electrohydrodynamic (EHD) jet printing to provide a vertical electrical interconnect structure through encapsulant 140. Conductive material 148 can be one or more layers of Al, Cu, Sn, Ni, Au, Ag, or other suitable electrically conductive material. FIG. 2g shows a top view of conductive material 148 in vias 144 through encapsulant 140.

In FIG. 2h, electrically conductive layer 150 is deposited, printed, or otherwise formed on surface 146 of encapsulant 140 to provide a horizontal electrical interconnect structure across, over, or through the encapsulant between electrical components 130a-130f and conductive material 148. Conductive layer 150 is electrically connected to conductive material 148. In one embodiment, conductive layer 150 is printed or dispensed onto surface 146 by printer or dispenser 151. Further detail of forming conductive layer 150 is described in FIGS. 5a-5b and 6. Conductive layer 150 can be one or more layers of a matrix, such as thermal set material or polymer, with graphene covered core shells embedded within the matrix, see further description in FIGS. 3a-3b and 4a-4c. Alternatively, electrically layer 150 is deposited onto surface 146 using evaporation, electrolytic plating, electroless plating, ball drop, screen printing process, injector, or EHD jet printing to provide a horizontal electrical interconnect structure across encapsulant 140 between electrical components 130a-130f and conductive material 148. Conductive layer 150 can be one or more layers of Al, Cu, Sn, Ni, Au, Ag, or other suitable electrically conductive material.

In FIG. 2i, electrical components 154a-154d are disposed on surface 146 of encapsulant 140 and electrically and mechanically connected to conductive layer 150. For example, electrical components 154a and 154c can be, or made similar to, semiconductor die 104 from FIG. 1c with bumps 114 oriented toward surface 146. Electrical components 154b and 154d can be discrete electrical devices, or IPDs, such as a diode, transistor, resistor, capacitor, and inductor. Alternatively, electrical components 154a-154d can include other semiconductor die, semiconductor packages, surface mount devices, RF components, discrete electrical devices, or IPD.

Electrical components 154a-154d are positioned over conductive layer 150 using a pick and place operation, similar to FIGS. 2b and 2c. Electrical components 154a-154d are brought into contact with conductive layer 150 and electrically connected thereto.

In FIG. 2j, encapsulant or molding compound 156 is deposited over electrical components 154a-154d and surface 146 of encapsulant 140 using a paste printing, compressive molding, transfer molding, liquid encapsulant molding, vacuum lamination, spin coating, or other suitable applicator. Encapsulant 156 can be liquid or granular polymer composite material, such as epoxy resin with filler, epoxy acrylate with filler, or polymer with proper filler. Encapsulant 156 is non-conductive, provides structural support, and environmentally protects the semiconductor device from external elements and contaminants.

An electrically conductive bump material is deposited over conductive layer 122 on surface 128 of substrate 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 158. In one embodiment, bump 158 is formed over a UBM having a wetting layer, barrier layer, and adhesive layer. Bump 158 can also be compression bonded or thermocompression bonded to conductive layer 122. In one embodiment, bump 158 is a copper core bump for durability and maintaining its height. Bump 158 represents one type of interconnect structure that can be formed over conductive layer 122. The interconnect structure can also use bond wires, conductive paste, stud bump, micro bump, or other electrical interconnect.

Substrate 120, electrical components 130a-130f, electrical components 154a-154d, encapsulant 140, and encapsulant 156 constitute reconstituted wafer or panel 160. In FIG. 2k, reconstituted wafer or panel 160 is singulated using saw blade or laser cutting tool 161 into individual semiconductor packages 162.

FIG. 2l illustrates semiconductor package 162 post singulation. Electrical components 130a-130f and/or electrical components 154a-154d may contain IPDs that are susceptible to or generate EMI, RFI, harmonic distortion, and inter-device interference. For example, the IPDs contained within electrical components 130a-130f and/or electrical components 154a-154d provide the electrical characteristics needed for high-frequency applications, such as resonators, high-pass filters, low-pass filters, band-pass filters, symmetric Hi-Q resonant transformers, and tuning capacitors. In another embodiment, electrical components 130a-130f and/or electrical components 154a-154d contain digital circuits switching at a high frequency, which could interfere with the operation of other IPDs.

To address EMI, RFI, harmonic distortion, and inter-device interference, shielding layer 164 is deposited, printed, or otherwise formed on surface 166 of encapsulant 156. Shielding layer 164 extends down side surfaces 168 and contacts conductive layer 122. Shielding layer 164 can be one or more layers of a matrix, such as thermal set material or polymer, with graphene covered core shells embedded within the matrix, see further description in FIGS. 3a-3b and 4a-4c. Alternatively, shielding layer 164 can be carbonyl iron, stainless steel, nickel silver, low-carbon steel, silicon-iron steel, foil, conductive resin, carbon-black, aluminum flake, Cu, Sn, Ni, Au, Ag, and other metals, composites, and conductive material capable of dissipating charged particles to ground. Shielding layer 164 is grounded through interconnect substrate 120.

The combination of substrate 120, electrical components 130a-130f, electrical components 154a-154d, encapsulant 140, encapsulant 156, and shielding layer 164 constitutes system-in-package (SiP) 180. SiP 180 is a 3D stacking package. Conductive material 148, conductive layer 150, and shielding layer 164 each constitute an interconnect structure including graphene covered core shells embedded within the matrix formed through or over the encapsulant.

FIGS. 3a and 3b show further detail of region or box 152 from FIG. 2f. In one embodiment, conductive material 148 includes matrix 314 and a plurality of cores 310 with graphene coating 312 as graphene core shells 316 embedded within the matrix, as shown in FIG. 3a. Matrix 314 can be a thermoset material, such epoxy resin or adhesive with filler containing alumina, Al, aluminum zinc oxide, or other material having good heat transfer and electrically conductive properties. Matrix 314 can be thermal grease such as silicon or polymer type such as polymethyl methacrylate (PMMA) or polyethylene terephthalate (PET). In one embodiment, core 310 is Ag, Cu, Ni, phase change material (PCM), or other suitable metal or similar material. Cores 310 are arranged within matrix 314 so that most if not all graphene coatings 312 covering the core contact at least one adjacent graphene coating to form a continuous and connecting electrical path 318 of graphene coatings through conductive material 148. A first graphene coating 312 contacts a second adjacent graphene coating, which in turn contacts a third adjacent graphene coating, and so on, to form continuous and connecting electrical path 318. Cores 310 have sufficient density that most if not all the graphene coatings around the cores contact at least one graphene coating around an adjacent core, and typically contact graphene coating of multiple adjacent cores. Graphene core shells 316 occupy space within matrix 314 between surface 317 of the matrix and surface 146 of encapsulant 140.

In another embodiment, matrix 314 is a polymer or composite epoxy with dispersed graphene, carbon nanotubes, conductive polymers, and the like. For example, matrix 314 can be a Ag ink epoxy for conductive material 148.

FIG. 3b shows another embodiment of region or box 152 from FIG. 2f. In this case, matrix 320 is solder containing one or more elements of Sn, lead (Pb), or indium (In). Again, core 160 can be Cu, Ni, PCM, or other suitable metal or similar material. Each core 310, as embedded in matrix 320, is surrounded or covered by graphene coating or shell 312. In one embodiment, a graphene paste or ink is formed around a Cu or Ag core as graphene core shell 316.

Cores 310 are arranged within matrix 320 so that most if not all graphene coatings 312 covering the core contact at least one adjacent graphene coating to form a continuous and connecting path 322 of graphene coatings through conductive material 148. Graphene coating 312 of each core 310 contacts the graphene coating of an adjacent core. A first graphene coating 312 contacts a second adjacent graphene coating, which in turn contacts a third adjacent graphene coating, and so on, to form continuous and connecting path 322. Cores 310 have sufficient density that most if not all the graphene coatings around the cores contact at least one graphene coating around an adjacent core, and typically contact graphene coating of multiple adjacent cores.

FIGS. 4a-4c illustrate further detail of core 310, graphene coating 312, and graphene core shell 316. In one embodiment, core 310 is Cu, Ni, PCM, or other suitable metal or similar material. FIG. 4b illustrates graphene coating 312 formed over and around surface 328 of core 310. FIG. 4c illustrates further detail of graphene coating 312 formed as a mesh network around surface 328 of core 310, collectively graphene core shell 316. Graphene 312 is an allotrope of carbon with one or more layers of carbon atoms each arranged in a two-dimensional (2D) honeycomb lattice. Graphene coating 312 can be formed by CVD. Core 310 is placed in a chamber heated to 900-1080° C. A gas mixture of CH₄/H₂/Ar is introduced into the chamber to initiate a CVD reaction. The carbon source decomposes in the high-temperature reaction chamber as the CVD reaction separates the carbon atoms from the hydrogen atoms, leaving graphene coating 312 on surface 328 of core 310. The release of carbon atoms over core 310 forms a continuous sheet of graphene coating 312. Additional information related to forming graphene coating by CVD is disclosed in U.S. Pat. No. 8,535,553, and hereby incorporated by reference.

Core 310 is PCM capable of phase change from solid to liquid phase or from liquid phase to solid phase within the operating temperature range of the semiconductor chip, e.g., 20-200° C. A first coating 330 is formed around PCM core 310, as shown in FIG. 4b and discussed in published Korean application KR101465616B1. The first coating 330 can be a polymer intermediate layer. A second coating 312 is formed over the first coating 330. Matrix 314 and 320 with graphene covered cores is further disclosed in U.S. Pat. No. 10,421,123, and all are incorporated herein by reference.

The properties of graphene are summarized in Table 1, as follows:

TABLE 1
Properties of graphene

| Parameter | | |
|---|---|---|
| Electronic mobility | 2 × 10⁵ | cm² V⁻¹ s⁻¹ |
| Current density | 10⁹ | A cm⁻¹ |
| Velocity of fermion (electron) | 10⁶ | m s⁻¹ |
| Thermal conductivity | 4000-5000 | W m⁻¹ K⁻¹ |
| Tensile strength | 1.5 | Tpa |
| Breaking strength | 42 | N m⁻¹ |
| Transparency | 97.7% | |
| Elastic limit | 20% | |
| Surface area | 2360 | m² g⁻¹ |

Graphene 312 has 100 times the electrical conductivity of Cu. Graphene 312 enables epoxy to exhibit electrical conductivity similar to Ag, while reducing or eliminating oxidation. Core shell 316 with Cu or Ag and graphene epoxy is low cost, as compared to sputtering. Graphene 312 has a low moisture permeability and a high thermal conductivity of 4000-5000 W m⁻¹ K⁻¹, 10 times higher than Cu at room temperature. Since carbon also has a good solderability and wettability of solder paste. Graphene 312 exhibits a high degree of flexibility and remains stable against warpage. Conductive material 148 with graphene Cu or Ag shells 316 improves electrical conductivity, while lowering manufacturing cost.

The above description in FIGS. 3a-3b and 4a-4c apply to material or layers 150 and 164.

FIG. 5a shows depositing conductive layer 150 over surface 146 of encapsulant 140 in SiP 180 using electrohydrodynamic (EHD) jet printing. SiP 180 is placed on substrate 340 capable of three dimensional (x, y, z directions) movement to control distribution of shielding material on surface 146. Pneumatic regulator 342 with pressure gauge applies pressure to syringe pump 344 containing shielding material, such as conductive and non-conductive ink. Conical section 346 narrows the ink path to injection nozzle 348, which deposits the ink on surface 146 of encapsulant 140 in a controlled manner. More specifically, injection nozzle 348 performs ink jetting by an electric field and pressure between the nozzle and substrate. In FIG. 5b, pressure is applied from pneumatic regulator 342. A voltage source induces an electric field shown as negative charges 350 and positive charges 352. The printed liquid is driven by the electric field to achieve direct pattern, high resolution printing of conductive layer 150.

FIG. 6 shows depositing conductive layer 150 over surface 146 of encapsulant 140 in SiP 180 using aerosol jet printing. Dispenser 360 includes channel 362 for the flow of shielding material, such as conductive and non-conductive ink, and channel 364 for the flow of a gas, such as nitrogen. The shielding material is mixed with the gas and deposits the ink from nozzle or head 370 on surface 146 of encapsulant 140 as an aerosol jet. The printed liquid, i.e., conductive layer 150 is dispensed as a jetting of aerosol focused by sheath gas at the end of head 370. The above description in FIGS. 5a-5b and 6 apply to material or layers 148 and 164.

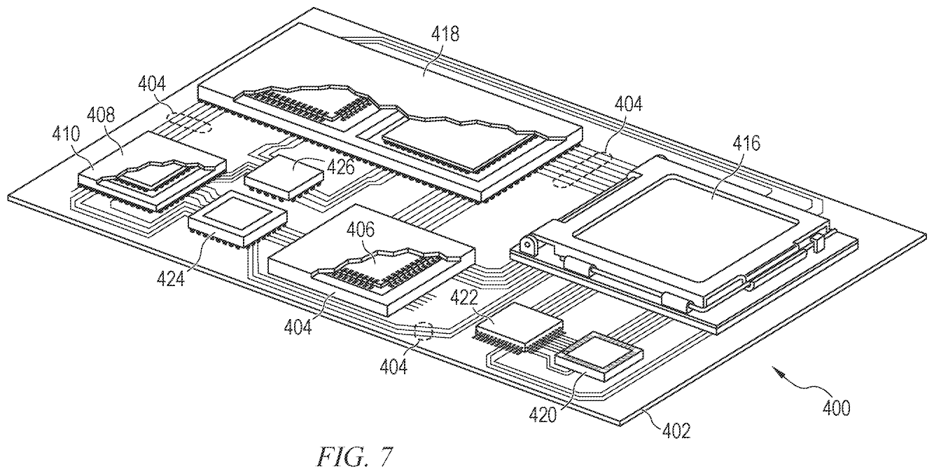

FIG. 7 illustrates electrical device 400 having a chip carrier substrate or PCB 402 with a plurality of semiconductor packages disposed on a surface of PCB 402, including SiP 180. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 7, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate;
a first electrical component disposed over the substrate;
a first encapsulant deposited over the first electrical component and substrate; and
an interconnect structure including a graphene core shell formed over or through the first encapsulant.

2. The semiconductor device of claim 1, further including:
a second electrical component disposed over the first encapsulant; and
a second encapsulant deposited over the second electrical component.

3. The semiconductor device of claim 2, further including a shielding layer formed over the second encapsulant.

4. The semiconductor device of claim 1, wherein the graphene core shell includes a copper core or silver core.

5. The semiconductor device of claim 1, wherein the interconnect structure includes a plurality of cores covered by graphene and the graphene is interconnected within the interconnect structure to form an electrical path.

6. The semiconductor device of claim 1, wherein the interconnect structure includes thermoset material or polymer or composite epoxy type matrix and the graphene core shell is embedded within the thermoset material or polymer or composite epoxy type matrix.

7. A semiconductor device, comprising:
a substrate;
a first encapsulant deposited over the substrate; and
an interconnect structure including a graphene core shell formed over or through the first encapsulant.

8. The semiconductor device of claim 7, further including:
a first electrical component disposed over the substrate;
a second electrical component disposed over the first encapsulant; and
a second encapsulant deposited over the second electrical component.

9. The semiconductor device of claim 8, further including a shielding layer formed over the second encapsulant.

10. The semiconductor device of claim 9, wherein the shielding layer includes a graphene core shell.

11. The semiconductor device of claim 7, wherein the graphene core shell includes a copper core or silver core.

12. The semiconductor device of claim 7, wherein the interconnect structure includes a plurality of cores covered by graphene and the graphene is interconnected within the interconnect structure to form an electrical path.

13. The semiconductor device of claim 7, wherein the interconnect structure includes thermoset material or polymer or composite epoxy type matrix and the graphene core shell is embedded within the thermoset material or polymer or composite epoxy type matrix.

14. A method of making a semiconductor device, comprising:
providing a substrate;
disposing an electrical component over the substrate;
disposing a first electrical component over the substrate;
depositing a first encapsulant over the first electrical component and substrate; and
forming an interconnect structure including a graphene core shell over or through the first encapsulant.

15. The method of claim 14, further including:
disposing a second electrical component over the first encapsulant; and
depositing a second encapsulant over the second electrical component.

16. The method of claim 15, further including forming a shielding layer over the second encapsulant.

17. The method of claim 14, wherein the graphene core shell includes a copper core or silver core.

18. The method of claim 14, wherein the interconnect structure includes a plurality of cores covered by graphene and the graphene is interconnected within the interconnect structure to form an electrical path.

19. The method of claim 14, wherein the interconnect structure includes thermoset material or polymer or composite epoxy type matrix and the graphene core shell is embedded within the thermoset material or polymer or composite epoxy type matrix.

20. A method of making a semiconductor device, comprising:
providing a substrate;
depositing a first encapsulant over the substrate; and
forming an interconnect structure including a graphene core shell over or through the first encapsulant.

21. The method of claim 20, further including:
disposing a first electrical component over the substrate;
disposing a second electrical component over the first encapsulant; and
depositing a second encapsulant over the second electrical component.

22. The method of claim 21, further including forming a shielding layer over the second encapsulant.

23. The method of claim 20, wherein the graphene core shell includes a copper core or silver core.

24. The method of claim 20, wherein the fi interconnect structure includes a plurality of cores covered by graphene and the graphene is interconnected within the interconnect structure to form an electrical path.

25. The method of claim 20, wherein the interconnect structure includes thermoset material or polymer or composite epoxy type matrix and the graphene core shell is embedded within the thermoset material or polymer or composite epoxy type matrix.
